(19) United States
(12) Patent Application Publication
(10) Pub. No.: US 2026/0293521 A1
(43) Pub. Date: Sep. 24, 2026

(54) DEVICE FOR RECOVERING ENERGY, VEHICLE AND FAIRGROUND RIDE COMPRISING SUCH A DEVICE

(71) Applicant: MACK RIDES GMBH & CO. KG, Waldkirch (DE)

(72) Inventor: Andreas FRIEDBERGER, Waldkirch (DE)

(21) Appl. No.: 19/168,912

(22) PCT Filed: Dec. 19, 2023
(86) PCT No.: PCT/EP2023/086632

§ 371 Date: Sep. 25, 2025

(30) Foreign Application Priority Data
Mar. 29, 2023 (DE) 10 2023 108 066.0

(51) Int. Cl. H10N 10/13; A63G 7/00

(52) U.S. Cl. CPC H10N 10/13; A63G 7/00

(57) ABSTRACT

The present invention relates to a device (3) for a fairground ride (1), in particular for a roller coaster, for recovering energy, having a component (10) which is to be cooled, a cooling apparatus (20) and at least one heat transmission means (30), wherein the cooling apparatus is arranged on a surface of the component which is to be cooled and comprises at least one first Peltier element (21), wherein the at least one first Peltier element (21) is arranged between the surface (11) of the component (10) which is to be cooled and the at least one heat transmission means (30), wherein the first Peltier element (21) is operated by generator and is connected electrically to a consumer (40), and wherein the at least one first Peltier element (21) energizes the consumer (40). The invention also relates to a fairground ride (1) comprising such a device (3).

The present invention relates to a device for a fairground ride, in particular for a roller coaster, for recovering energy. In addition, the present invention relates to a vehicle of a fairground ride with such a device having the features of claim 8 and a ride having the features of claim 10.

Fairground rides are known from prior art in various configurations and are provided as stationary or semi-stationary installations or attractions, in particular in amusement parks, for the leisure entertainment of passengers. Generic fairground rides can be, for example, water rides, roller coasters, dark rides, merry-go-rounds, roundabouts or similar, which have at least one passenger seat in which the at least one passenger can ride along a track. The at least one passenger seat may be arranged on a vehicle or a movable frame, for example.

Generic fairground rides have proven themselves in the past, but it has been shown that large amounts of heat energy are dissipated from brakes and stators during a ride without being utilized.

In addition, it has become apparent that supplying the vehicles with electrical energy is a complex undertaking. On the one hand, electricity storage units have to be carried, which weigh down vehicles considerably. On the other hand, the electricity storage units have to be charged regularly, for which the vehicles have to be taken to a maintenance area, for example.

Based on this prior art, the present invention is dedicated to the object of providing a device for recovering energy which expediently eliminates the disadvantages known from prior art. In addition, the device which is to be proposed should be able to ensure a self-sufficient energy supply, in particular to a vehicle of a fairground ride.

These objects are achieved by a device with the features of claim 1.

Further advantageous embodiments of the present invention are given in the dependent claims.

The device according to the invention with the features of claim 1 for a fairground ride, in particular for a roller coaster, for recovering energy has a component which is to be cooled, a cooling apparatus and at least one heat transmission means. The cooling apparatus is thermally coupled to a surface of the component which is to be cooled and comprises at least one first Peltier element, wherein the at least one first Peltier element is arranged between the surface of the component which is to be cooled and the at least one heat transmission means.

According to the invention, the first Peltier element is operated by generator and is connected electrically to a consumer. The at least one first Peltier element energizes the consumer

The present invention is based on the idea of using the high thermal energy, in particular at brakes and stators of fairground rides, in particular roller coasters, for energizing at least one consumer. This is intended to recover the energy that would otherwise be lost to the environment. This recovered energy can then be used to energize the at least one consumer.

It has been shown that a device according to the proposal can recover sufficient energy, for example, to provide a vehicle of a fairground ride with sufficient energy during the ride with the fairground ride. In this way, for example, vehicles of a roller coaster according to the invention can be operated in a simple and cost-effective manner, in particular also with low maintenance, and independently supply themselves with energy. To this end, the present invention provides for the at least one first Peltier element to be operated by generator utilizing the Seebeck effect. The at least one first Peltier element is arranged on the component which is to be cooled, preferably on the surface, in such a manner that a hot side is thermally coupled to the surface of the component which is to be cooled and a cold side is coupled to the at least one heat transmission means. The at least one heat transmission means preferably has an increased surface area and is preferably convection-cooled.

A preferred further development of the present invention provides that the consumer comprises an electricity storage unit, in particular an electricity storage unit of the vehicle. The electricity storage unit can, for example, temporarily store the electricity generated by the cooling apparatus and can in turn be used, for example, to energize sensors and/or safety apparatuses of the at least one vehicle of the ride, in particular the roller coaster.

In addition, it has proven to be advantageous if the consumer comprises at least one second Peltier element. The at least one second Peltier element can be used, for example, to cool an object or any component, such as the component which is to be cooled.

In the simplest case, the at least one first Peltier element can energize the at least one second Peltier element, wherein the second Peltier element is used to cool the component which is to be cooled. In this case, both the first Peltier element as well as the second Peltier element are thermally coupled or connected to the component which is to be cooled.

According to an advantageous embodiment, the at least one second Peltier element can be thermally coupled to the component which is to be cooled. In particular, it is preferred if the at least one second Peltier element is arranged on the surface of the component which is to be cooled, adjacent to the first Peltier element.

In addition, it has also proven to be advantageous if a cooling side of the at least one second Peltier element is thermally coupled to the component. In this manner, the at least one second Peltier element can contribute to increasing the cooling performance on the component which is to be cooled with the energy recovered from the first Peltier element.

Furthermore, a preferred further development of the present invention provides for a heating side of the at least one second Peltier element being thermally coupled to the at least one heat transmission means. The heating side of the at least one second Peltier element can either be thermally coupled with its own, i.e. at least one second heat transmission means, or with the at least one heat transmission means, which is thermally coupled with the first Peltier element.

The thermal coupling of the at least one first Peltier element and/or the at least one second Peltier element with the component or components which is/are to be cooled and/or with the at least one heat transmission means can be achieved by a direct or an indirect connection. Preferably, the thermal coupling can be achieved by means of a bonding layer, wherein the bonding layer can be formed, for example, from a thermally conductive paste or a thermally conductive bonding agent.

A further embodiment of the present invention provides for the at least one heat transmission means comprising cooling ribs and/or cooling fins. Further, it can be provided that the at least one heat transmission means comprises one or more heat pipes through which a large amount of heat can be transmitted, for example to a heat sink with an increased surface area for improved convection cooling.

A further aspect of the present invention relates to a vehicle of a fairground ride, in particular a vehicle of a roller coaster, having a previously described device for recovering energy.

According to a preferred further development, it can be advantageous if the at least one device is arranged on a brake and/or a stator of the vehicle. In particular, brakes and/or stators exhibit very high temperature development when braking and accelerating a vehicle, in particular a vehicle of a roller coaster. The resulting thermal energy can be at least partially recovered and, in particular, used to energize the at least one consumer.

A third and final aspect of the present invention relates to a fairground ride comprising a vehicle and at least one previously described device for recovering energy.

An exemplary embodiment is described in detail below with reference to the accompanying FIGURE.

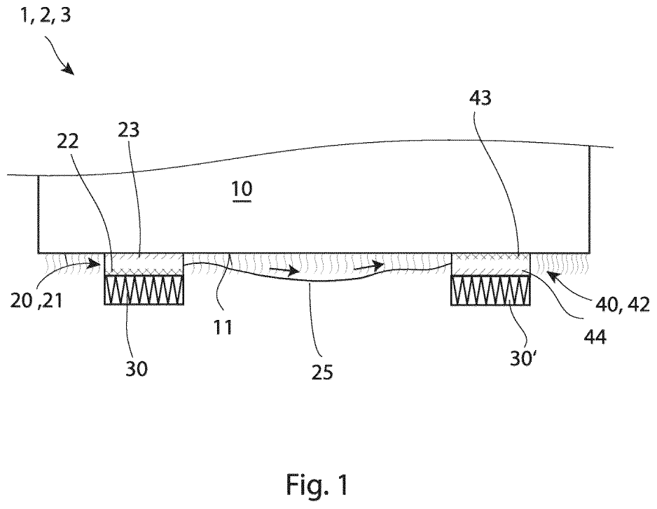

FIG. 1 shows a highly simplified and schematically illustrated device 3 for recovering energy on a vehicle 2 of a fairground ride 1. Such a fairground ride 1 can be a roller coaster, for example, wherein the vehicle 2 can travel along a track (not shown).

The at least one vehicle 2 of the fairground ride 1 preferably does not have its own drive apparatus. The fairground ride 1 comprises at least one lift hill (not shown) and/or a launch section (not shown), which allows the at least one vehicle 2 to travel along the track without active acceleration.

FIG. 1 shows a section of the vehicle 2 comprising the device 3 for recovering energy. A component 10 of the at least one vehicle 2 is shown, wherein the component 10 can experience a very high temperature development, for example when braking and/or accelerating the vehicle 3.

The device 3 comprises the component 10 which is to be cooled, a cooling apparatus 20 and heat transmission means 30.

The cooling apparatus 20 is arranged on a surface 11 of the component 10 which is to be cooled and comprises at least one first Peltier element 21, which is arranged between the surface 11 of the component 10 which is to be cooled and the at least one heat transmission means 30.

The first Peltier element 21 has a cold side 22 and a hot side 23, wherein the hot side 23 is facing the component 10 which is to be cooled and the cold side 22 is facing the heat transmission means 30.

The first Peltier element 21 can be operated by generator using the Seebeck effect, so that in the event of a temperature difference, the first Peltier element 21 can output an electrical voltage that can enable the self-sufficient supplying of voltage to the vehicle 2.

In the illustrated exemplary embodiment, the first Peltier element 21 is electrically connected to a consumer 40 via an electrical wire 25, wherein the consumer 40 can be, for example, an electricity storage unit or the supply network of the vehicle 3. For example, the electricity storage unit can energize electrical monitoring systems of the vehicle 2, wherein the electricity storage unit can be charged by the at least one first Peltier element 21 during operation of the fairground ride 1.

In the illustrated exemplary embodiment, the consumer 40 is a second Peltier element 42, which is electrically connected to the first Peltier element 21. The first Peltier element 21 energizes the second Peltier element 42.

The second Peltier element 42 has a cooling side 43 and a heating side 44, wherein when energized by the Peltier effect, the cooling side 43 experiences a temperature reduction and the heating side 44 experiences a temperature increase.

In the exemplary embodiment illustrated, the second Peltier element 42 is also thermally coupled to the component 10 which is to be cooled. It should be noted here that the second Peltier element 42 can be thermally coupled or connected to any component of the vehicle 3.

The second Peltier element 42 is arranged on the surface 11 of the component 10 which is to be cooled spaced apart from the first Peltier element 21. The cooling side 43 faces the component 10 which is to be cooled, and the heating side 44 faces a second heat transmission means 30, which is designated by reference number 30′ in the accompanying FIGURE for better understanding. The second Peltier element can increase the cooling performance locally on the component 10.

The heat transmission means 30 can be a heat transmitter of any design, also known colloquially as a heat exchanger. In the illustrated exemplary embodiment, the heat transmission means 30 comprise several cooling ribs or cooling fins that can be cooled by convection.

### LIST OF REFERENCE NUMBERS

1 fairground ride
2 vehicle
3 device
10 component
11 surface
20 cooling apparatus
21 first Peltier element
22 cold side
23 hot side
25 electrical wire
30 heat transmission means
40 consumer
42 second Peltier element
43 cooling side
44 heating side

1. A device (3) for a fairground ride (1), in particular for a roller coaster, for recovering energy, having
a component (10) which is to be cooled,
a cooling apparatus (20) and
at least one heat transmission means (30),
wherein the cooling apparatus is arranged on a surface of the component which is to be cooled and comprises at least one first Peltier element (21),
wherein the at least one first Peltier element (21) is arranged between the surface (11) of the component (10) and the at least one heat transmission means (30), and
wherein the first Peltier element (21) is operated by generator and is connected electrically to a consumer (40), and
wherein the at least one first Peltier element (21) energizes the consumer (40).

2. The device (3) according to claim 1,
characterized in that
the consumer comprises an electricity storage unit, in particular an electricity storage unit of the vehicle.

3. The device (3) according to claim 1,
characterized in that
the consumer (40) comprises at least one second Peltier element (42).

4. The device (3) according to claim 1, characterized in that
the at least one second Peltier element (42) is thermally coupled to the component (10) which is to be cooled, in particular in that the at least one second Peltier element (42) is arranged on the surface (11) of the component which is to be cooled.

5. The device (3) according to claim 1, characterized in that
a cooling side (43) of the at least one second Peltier element (42) is thermally coupled to the component (10).

6. The device (3) according to claim 1, characterized in that
a heating side (44) of the at least one second Peltier element (42) is thermally coupled to the at least one heat transmission means (30).

7. The device (3) according to any claim 1, characterized in that
the at least one heat transmission means (30) comprises cooling ribs and/or cooling fins.

8. A vehicle (2) of a fairground ride (1), in particular a roller coaster, having a device (3) according to claim 1.

9. The vehicle (2) according to claim 8,
characterized in that
the device (3) is arranged on at least one brake and/or at least one stator.

10. A fairground ride (1) comprising a vehicle (2) and at least one device (3) according to claim 1.
